(19) United States
(12) Patent Application Publication
(10) Pub. No.: US 2007/0019827 A1
(43) Pub. Date: Jan. 25, 2007

(54) Digital amplifier for a personal computer

(76) Inventor: Il Won Lee, Cheonan-si (KR)

Correspondence Address: ATTN: Intellectual Property Department;Porter, Wright, Morris & Arthur LLP, 28th Floor, 41 South High Street, Columbus, OH, 43215-6194, US

(21) Appl. No.: 11/246,970

(22) Filed: Oct. 7, 2005

(30) Foreign Application Priority Data
Jul. 21, 2005 (KR) 2005-66424

(51) Int. Cl. H03F 21/00

(52) U.S. Cl. 381/120

(57) ABSTRACT

The present invention provides a digital amplifier connected to a personal computer using USB, which can be easily installed in the PC and immediately used without installing a further driver in desktop and laptop computers, and which can have various additional input/output functions according to a user's needs. The digital amplifier comprises a PCM converter (10); a USB interface (20) connected to a USB port (21) of the PC; an A/D converter (30); a DIR (40); and a multi-channel speaker (50).

### FIELD OF THE INVENTION

The present invention relates to a digital amplifier for a personal computer, and more particularly to a digital amplifier which is connected to a PC by using USB (Universal Serial Bus), so that it can be easily installed in the PC and immediately used without installing a further driver in desktop and laptop computers, and it can also have various additional input/output functions according to a user's needs.

### BACKGROUND OF THE INVENTION

In general, a digital amplifier for a personal computer is an electronic device to play digital sounds stored in the PC and output the digital sounds to the outside through a speaker connected to the PC. Compared to an analog amplifier, the digital amplifier is compact and cheap, and economical in the consumption of electric power. The digital amplifier can be used universally and has good compatibility, so that its use has been increasing.

The digital amplifier is usually installed in the PC, and can be replaced with another one having other various functions as per a user's demands.

Recently, the digital amplifier has been developed to have various additional functions. For example, as shown in FIG. 3, the digital amplifier (1) is connected to a desktop PC (2) or a notebook PC (3). It receives sound signals from a DVD (4) or an audio (5), which is capable of data communication, and it coverts the sound signals to digital sound signals through quantization and sampling processes, so that the digital sounds can be output through a speaker (6) having various outputs such as 5.1 channels. Also, the digital amplifier (1) functions to have the digital sound signals stored in the desktop PC (2) or the notebook PC (3).

However, in spite of the above advantages of the digital amplifier, there was a disadvantage that in order to install the digital amplifier, a user had to open the PC directly and fit the digital amplifier into one of slots in a main board of the PC.

Further, since the number of slots in the main board was limited, extensibility of the digital amplifier deteriorated, and due to the limitation of available space, it was difficult to add further amplifiers having various outputs.

Particularly, in case of an on-board digital amplifier, which was manufactured integrally with the main board of the PC, it was much more difficult to have additional functions to meet a user's demands.

Furthermore, when the digital amplifier is to be replaced, it was necessary to install a new driver to use a new digital amplifier, which was inconvenient.

In the meantime, USB (Universal Serial Bus) has been generally used as a port for a PC. It can be directly connected to peripheral devices without disassembly of the PC and complicated line connections.

The USB supports the functions of Plug & Play and Hot Plugging, and also supports transmission speed still faster than that of a conventional serial/parallel port. It can have extensions to connect up to 127 devices.

### SUMMARY OF THE INVENTION

An object of the present invention is to provide a digital amplifier, which is connected to a PC by using USB, to be easily installed in the PC and immediately used without installing a further driver in desktop and laptop computers.

Another object of the present invention is to provide a digital amplifier connected to a PC using USB, which can have various additional input/output functions according to a user's needs.

A further object of the present invention is to provide a digital amplifier for a PC, which is more convenient to use, thereby improving commerciality.

In order to achieve the above objects, the digital amplifier for a PC according to the present invention comprises:

a PCM (pulse code modulation) converter to control multi-channel sound signals by encoding digital sound signals by pulse amplitude modulation;

a USB interface connected to a USB port of the PC to transmit the digital sound signals from the USB port to the PCM converter;

an A/D converter to convert analog sound signals received from an analog audio to digital sound signals;

a DIR (Digital Interface Relax) to transmit digital sound signals from a digital audio or the digital sound signals converted by the A/D converter to the PCM converter; and

a multi-channel speaker to output the multi-channel sound signals controlled by the PCM converter to the outside.

The digital amplifier connected to the PC using the USB according to the present invention makes it easier to install the digital amplifier and to add various input/output functions. Further, the digital amplifier can be instantly used without installing a further driver and used for desktop and notebook computers. It can also have a combination of various functions according to a user's needs.

### BRIEF DESCRIPTION OF THE DRAWINGS

The accompanying drawings, which are included to provide a further understanding of the invention and are incorporated in and constitute a part of this specification, illustrate an embodiment of the invention and together with the description serve to explain the principles of the invention, wherein:

FIG. 1 is a block diagram of a digital amplifier connected to a PC using USB according to the present invention;

FIG. 2 is a detailed block diagram of a PCM converter in FIG. 1; and

FIG. 3 is a block diagram showing a state where a conventional amplifier is used.

### DETAILED DESCRIPTION OF THE PREFERRED EMBODIMENTS

Reference will now be made in detail to preferred embodiments of the present invention in conjunction with the accompanying drawings.

The digital amplifier connected to a PC using USB according to the present invention comprises a PCM converter (10) to control multi-channel sound signals by encoding digital sound signals by pulse amplitude modulation; a USB interface (20) connected to a USB port (21) of the PC to transmit the digital sound signals from the USB port (21) to the PCM converter (10); an A/D converter (30) to convert analog sound signals received from an analog audio (31) to digital sound signals; a DIR (40) to transmit digital sound signals from a digital audio (41) or the digital sound signals converted by the A/D converter (30) to the PCM converter (10); and a multi-channel speaker (50) to output the multi-channel sound signals controlled by the PCM converter (10) to the outside.

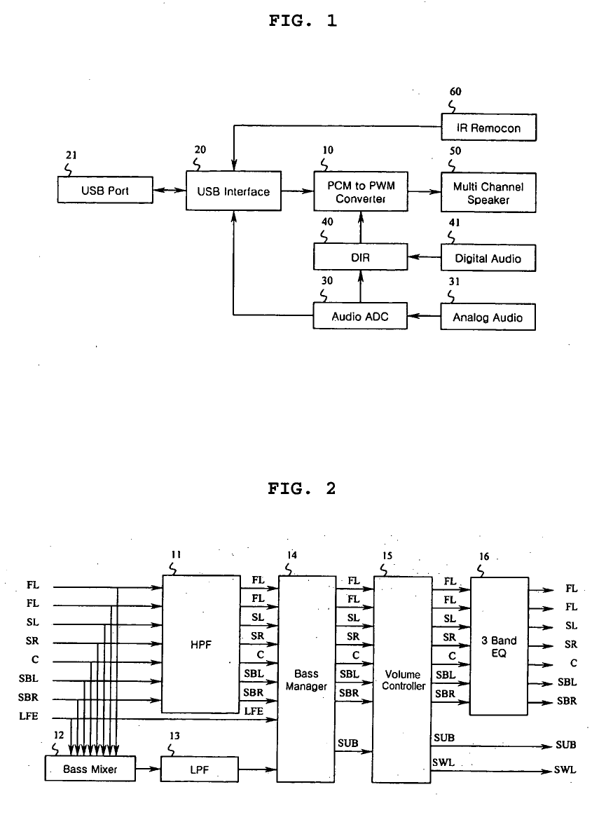

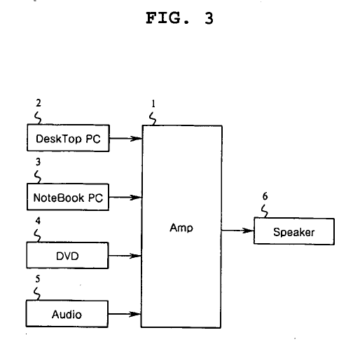

Referring to FIG. 1, the digital amplifier is connected to the USB port (21), the analog audio (31) and the digital audio (41) and it processes sound signals transmitted from the USB port (21), the analog audio (31) and the digital audio (41) to output digital sounds through the speaker (50).

In FIG. 2, procedures for processing the sound signals transmitted from the USB port (21), the analog audio (31) and the digital audio (41) in the PCM converter (10) are shown in detail.

The PCM converter (10) comprises a high pass filter (11), a bass mixer (12), a low pass filter (13), a bass manager (14), a volume controller (15) and an equalizer (16), to control the multi-channel sound signals by encoding the digital sound signals by pulse amplitude modulation.

The high pass filter (11) is to extract high-frequency elements from the multi-channel sound signals input thereto. The bass mixer (12) extracts the same multi-channel sound signals as those input to the high pass filter (11) and transmits them to the low pass filter (13). The low pass filter (13) is to extract low-frequency elements from the multi-channel sound signals, which have been extracted by the bass mixer (12).

Detailed structure of circuits for the high pass filter (11), the bass mixer (12) and the low pass filter (13) may be constructed to be varied and modified according to needs of those skilled in the art.

The bass manager (14) is to control individually volume levels of the high-frequency elements and the low-frequency elements extracted by the high pass filter (11) and the low pass filter (13), respectively. It classifies the multi-channel sound signals according to their respective channels and then controls the volume levels of the respective channels.

The volume controller (15) is to integrally control the volume levels of the multi-channel sound signals controlled by the bass manager (14). That is, it integrates the respective sound signals, which have been controlled for their respective channels by the bass manager (14), into one multi-channel sound signal and then controls the volume level thereof.

The equalizer (16) is to compensate and equalize the multi-channel sound signal output from the volume controller (15). That is, it compensates modifications occurring in the course of amplifying or transmitting signals and equalizes them by integrating characteristics of the multi-channel sound signal.

In addition, the USB interface (20) is connected to the USB port (21) of the PC to receive the digital sound signals and transmit them to the PCM converter (10). In the USB interface (20), the data transmitted to the USB port (21) is converted into signals that can be processed in the PCM converter (10).

The A/D converter (30) converts analog sound signals received from the analog audio (31) to digital sound signals. Specifically, it converts the analog sound signals to digital ones through quantization and sampling processes.

In this case, since the magnitude of the digital signals varies depending on the number of quantization levels and the time for sampling, the number of quantization levels and the time for sampling are determined in accordance with a processing mode of the PCM converter (10).

The DIR (40) serves to transmit the digital sound signals transmitted from the digital audio (41) or the digital sound signals converted in the A/D converter (30) to the PCM converter (10).

The multi-channel speaker (50) is a device to output the multi-channel sound signals controlled by the PCM converter (10) to the outside.

In addition, the digital amplifier according to the present invention may further comprise an infrared remote controller (60) capable of wireless data communication with the USB interface (20). Therefore, by using the infrared remote controller (60), a user can remotely control the signals processed in the PCM converter (10).

Specifically, control signals output from the infrared remote controller (60) are transmitted to the PCM converter (10) via the USB interface (20), and the PCM converter (10) controls the multi-channel sound signals in accordance with the transmitted control signals.

It is also noted that the infrared remote controller (60) may directly control software of the PC.

It will be apparent to those skilled in the art that various modifications and variations can be made to the present invention without departing from the spirit and scope of the invention. The present invention covers the modifications and variations thereof provided they come within the scope of the appended claims and their equivalents.

What is claimed is:

1. A digital amplifier for a PC comprising:
a PCM converter (10) to control multi-channel sound signals by encoding digital sound signals by pulse amplitude modulation;
a USB interface (20) connected to a USB port (21) of the PC to transmit the digital sound signals from the USB port (21) to the PCM converter (10);
an A/D converter (30) to convert analog sound signals received from an analog audio (31) to digital sound signals;
a DIR (40) to transmit digital sound signals from a digital audio (41) or the digital sound signals converted by the A/D converter (30) to the PCM converter (10); and
a multi-channel speaker (50) to output the multi-channel sound signals controlled by the PCM converter (10) to the outside.

2. The digital amplifier as claimed in claim 1, wherein the PCM converter (10) comprises:
a high pass filter (11) to extract high-frequency elements from the multi-channel sound signals input thereto;
a bass mixer (12) to extract the multi-channel sound signals input to the high pass filter (11);
a low pass filter (13) to extract low-frequency elements from the multi-channel sound signals which have been extracted by the bass mixer (12);
a bass manager (14) to control individually volume levels of the high-frequency elements and the low-frequency elements extracted by the high pass filter (11) and the low pass filter (13), respectively;
a volume controller (15) to integrally control the volume levels of the multi-channel sound signals controlled by the bass manager (14); and
an equalizer (16) to compensate and equalize the multi-channel sound signal output from the volume controller (15).

3. The digital amplifier as claimed in claim 1 or 2, further comprising an infrared remote controller (60) capable of wireless data communication with the USB interface (20).
